(19) United States
(12) Patent Application Publication
(10) Pub. No.: US 2024/0234093 A1
(43) Pub. Date: Jul. 11, 2024

(54) SUBSTRATE PROCESSING APPARATUS

(71) Applicant: SAMSUNG ELECTRONICS CO., LTD., Suwon-si (KR)

(72) Inventors: Sejin OH, Suwon-si (KR); Dougyong Sung, Suwon-si (KR)

(73) Assignee: SAMSUNG ELECTRONICS CO., LTD., Suwon-si (KR)

(21) Appl. No.: 18/235,653

(22) Filed: Aug. 18, 2023

(30) Foreign Application Priority Data
Jan. 10, 2023 (KR) 10-2023-0003319

(51) Int. Cl. H01J 37/32

(52) U.S. Cl. CPC H01J 37/32174; H01J 37/32422; H01J 37/3244; H01J 2237/334

(57) ABSTRACT

A substrate processing apparatus includes a chamber including an upper chamber defining a first plasma region for generating first plasma and a lower chamber defining a second plasma region for generating second plasma; a substrate support below the first and second plasma regions in the lower chamber, and configured to support a substrate; distribution plates between the first and second plasma regions in the upper chamber, and configured to inject ions included in the first plasma onto the substrate; a first plasma generating device on a side of the upper chamber and configured to generate the first plasma from a first process gas; a second plasma generating device on a side of the lower chamber and configured to generate the second plasma from a second process gas; and a controller that alternately operates the first plasma generating device and the second plasma generating device.

### CROSS-REFERENCE TO RELATED APPLICATION

This application claims benefit of priority to Korean Patent Application No. 10-2023-0003319, riled on Jan. 10, 2023, in the Korean Intellectual Property Office, the disclosure of which is incorporated herein by reference in its entirety.

### BACKGROUND

Embodiments of the present disclosure relate to a substrate processing apparatus.

In order to manufacture a semiconductor device, a series of processes such as a deposition process, an etching process, a cleaning process, and the like, may be performed. These processes may be performed by a substrate processing apparatus such as a deposition device, an etching device, and/or a cleaning device, having a process chamber. For example, in the etching process using a plasma processing technique, a substrate processing apparatus for etching a material layer on a substrate, using radicals and ions included in plasma, may be used.

### SUMMARY

According to embodiments of the present disclosure, a substrate processing apparatus capable of independently controlling radicals may be provided.

According to embodiments of the present disclosure, a substrate processing apparatus is provided. The substrate processing apparatus includes: a chamber including an upper chamber defining a first plasma region for generating first plasma, and the chamber further including a lower chamber defining a second plasma region for generating second plasma; a substrate support below the first plasma region and the second plasma region in the lower chamber, and configured to support a substrate; distribution plates between the first plasma region and the second plasma region in the upper chamber, and configured to inject ions included in the first plasma onto the substrate; a first gas supply device configured to supply a first process gas to the first plasma region of the upper chamber; a second gas supply device configured to supply a second process gas to the second plasma region of the lower chamber; a first plasma generating device on at least one side of the upper chamber and configured to generate the first plasma from the first process gas; a second plasma generating device on at least one side of the lower chamber and configured to generate the second plasma from the second process gas; and a controller configured to alternately operate the first plasma generating device and the second plasma generating device.

According to embodiments of the present disclosure, a substrate processing apparatus is provided. The substrate processing apparatus includes: a chamber including an upper chamber defining a first plasma region, and the chamber further including a lower chamber defining a second plasma region; a substrate support in the lower chamber and configured to support a substrate; a first gas supply device configured to supply a first process gas to the first plasma region of the upper chamber; a second gas supply device configured to supply a second process gas to the second plasma region of the lower chamber; a first plasma generating device on at least one side of the upper chamber and configured to generate first plasma from the first process gas; and a second plasma generating device disposed on at least one side of the lower chamber and configured to generate second plasma from the second process gas, wherein a width of the second plasma region is greater than a width of the first plasma region.

According to embodiments of the present disclosure, a substrate processing apparatus is provided. The substrate processing apparatus includes: a first plasma generating device configured to generate first plasma in a first plasma region of the substrate processing apparatus; a second plasma generating device configured to generate second plasma in a second plasma region of the substrate processing apparatus; a substrate support below the second plasma region and configured to support a substrate; and a controller configured to process the substrate using ions included in the first plasma and radicals included in the second plasma.

### BRIEF DESCRIPTION OF DRAWINGS

The above and other aspects, features, and advantages of embodiments of the present disclosure will be more clearly understood from the following detailed description, taken in conjunction with the accompanying drawings, in which:

FIG. 1 is a schematic cross-sectional view of a substrate processing apparatus according to an example embodiment.

FIG. 2A is a cross-sectional view of a substrate processing apparatus according to an example embodiment.

FIG. 2B is a cross-sectional view of a substrate processing apparatus according to an example embodiment.

FIG. 2C is a cross-sectional view of a substrate processing apparatus according to an example embodiment.

FIG. 3 is a schematic cross-sectional view of a substrate processing apparatus according to an example embodiment.

FIG. 4 is a schematic cross-sectional view of a substrate processing apparatus according to an example embodiment.

FIG. 5 is a flowchart illustrating a substrate processing method using a substrate processing apparatus according to example embodiments.

FIG. 6A is a first view illustrating the substrate processing method of FIG. 5 according to a process sequence.

FIG. 6B is a second view illustrating the substrate processing method of FIG. 5 according to the process sequence.

FIG. 6C is a third view illustrating the substrate processing method of FIG. 5 according to the process sequence.

FIG. 6D is a fourth view illustrating the substrate processing method of FIG. 5 according to the process sequence.

FIG. 6E is a fifth view illustrating the substrate processing method of FIG. 5 according to the process sequence.

FIG. 6F is a sixth view illustrating the substrate processing method of FIG. 5 according to the process sequence.

### DETAILED DESCRIPTION

Hereinafter, with reference to the accompanying drawings, non-limiting example embodiments of the present disclosure will be described as follows. Unless otherwise specified, in this specification, terms such as “an upper portion,” “an upper surface,” “a lower portion,” “a lower surface,” “a side surface,” and the like may be based on the drawings, and in fact, may be changed, depending on directions in which components are arranged.

It will be understood that when an element is referred to as being “on,” “connected to,” or “coupled to” another element, it can be directly on, connected to, or coupled to the other element or intervening elements may be present. In contrast, when an element is referred to as being “directly on,” “directly connected to,” or “directly coupled to” another element, there are no intervening elements present.

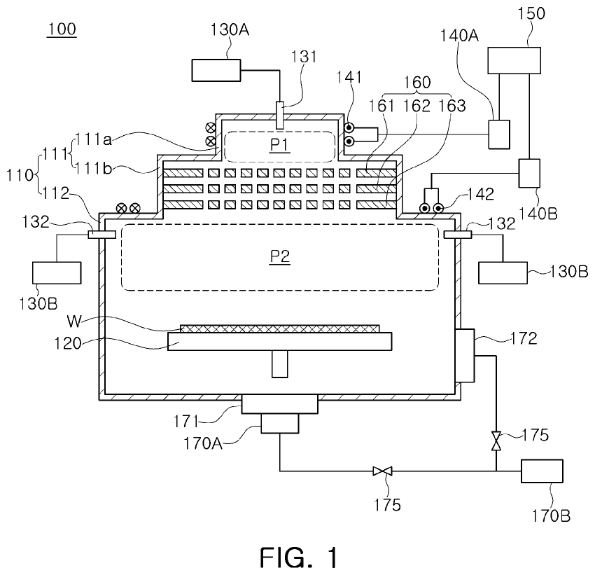

FIG. 1 is a schematic cross-sectional view of a substrate processing apparatus 100 according to an example embodiment.

Referring to FIG. 1, a substrate processing apparatus 100 according to an example embodiment may include a chamber 110, a substrate support 120, a first gas supply device 131 (e.g., a first gas supplier), a second gas supply device 132 (e.g., a second gas supplier), a first plasma generating device 141 (e.g., a first plasma generator), a second plasma generating device 142 (e.g., a second plasma generator), a first pressure regulator 171, and a second pressure regulator 172. According to an example embodiment, the substrate processing apparatus 100 may further include a controller 150 and/or distribution plates 160. Embodiments of the present disclosure may form first plasma and second plasma in separate regions in the chamber 110, respectively, to independently control an ion density and an ion energy of the first plasma and to independently control a radical density of the second plasma. Therefore, the substrate processing apparatus 100, according to example embodiments, may more effectively perform a processing process of a substrate, for example, an etching process of the substrate.

The substrate processing apparatus 100 may be a dry etching apparatus that performs an etching process on a substrate W provided on the substrate support 120 using plasma. According to embodiments, the substrate processing apparatus 100 may be a dry cleaning apparatus that performs etching cleaning. In the present embodiment, although the substrate processing apparatus 100 is illustrated as using an inductively coupled plasma (ICP) method, a plasma formation method of the substrate processing apparatus 100 is not limited thereto. The substrate W may be, for example, a silicon wafer used for manufacturing a semiconductor device such as a semiconductor integrated circuit (IC).

The chamber 110 may provide a space in which plasma is formed and a space in which an etching process is performed. The chamber 110 may provide a sealed internal space in which the substrate W is processed. The chamber 110 may include an upper chamber 111 providing a first plasma region P1 in which the first plasma is formed, and a lower chamber 112 providing a second plasma region P2 in which the second plasma is formed. For example, the first plasma region P1 may be defined by the upper chamber 111, and the second plasma region P2 may be defined by the lower chamber 112, but a shape and a configuration of the chamber 110 are not limited thereto. The upper chamber 111 may include an ion supplier 111a in which the first plasma region P1 is formed, and an ion distributor 111b configured to inject ions included in the first plasma onto the substrate W. In an example embodiment, a width of the ion distributor 111b may be greater than a width of the ion supplier 111a, but a shape and a configuration of the upper chamber 111 are not limited thereto. A passage through which the substrate W is inserted and removed may be provided on one side of the chamber 110. Alternatively, the substrate W may be inserted and removed while the lower chamber 112 is separated from the upper chamber 111. The chamber 110 may be formed of a metal material, and may include, for example, aluminum (Al) or an alloy thereof.

The substrate support 120 may be located below the chamber 110, and may support the substrate W while the substrate W is processed. For example, the substrate support 120 may be disposed below the first plasma region P1 and the second plasma region P2, and support the substrate W. The substrate support 120 may include an electrostatic chuck that fixes the substrate W by electrostatic force. The substrate support 120 may include a heater setting a temperature of the substrate W, a susceptor, or the like. The substrate support 120 may be configured to raise and lower the substrate W.

The first gas supply device 131 and the second gas supply device 132 may supply a process gas for plasma generation into the chamber 110. The first gas supply device 131 may be configured to supply a first process gas to the first plasma region P1 of the upper chamber 111, and the second gas supply device 132 may be configured to supply a second gas to the second plasma region P2 of the lower chamber 112. The first gas supply device 131 may be connected to a first gas supply source 130A supplying the first process gas. The first process gas may be a source gas generating the first plasma. The first process gas may include an inert gas. The inert gas may include, for example, at least one from among He, Ne, Ar, Kr, and Xe. The second gas supply device 132 may be connected to a second gas supply source 130B supplying the second process gas. The second process gas may be a source gas generating radical-dominant plasma. The second process gas may include, for example, an etching gas containing at least one from among Cl₂, HCl, CHF₃, CH₂F₂, CH₂F₂, H₂, BC₃, SiCl₄, Br₂, HBr, NF₃, CF₄, C₂F₄, C₄F₆, C₄F₈, SF₆, O₂, SO₂, and COS, but is not limited thereto, and types of the first and second process gases may be changed, depending on a composition of a material to be processed.

The first plasma generating device 141 and the second plasma generating device 142 may generate plasma from the process gas. Radio frequency (RF) power in a form of electromagnetic waves having a predetermined frequency and intensity may be applied to the first plasma generating device 141 and the second plasma generating device 142. The first plasma generating device 141 may be disposed on at least one side of the upper chamber 111, and may be configured to generate the first plasma from the first process gas. The second plasma generating device 142 may be disposed on at least one side of the lower chamber 112, and may be configured to generate the second plasma from the second process gas. The first plasma generating device 141 and the second plasma generating device 142 may generate plasma having a high ratio of radicals to ions. In an example embodiment, an electron temperature of the second plasma may be lower than an electron temperature of the first plasma. The ratio of radicals to ions in the first and second plasma may range from about 100:1 to about 10000:1. According to an example embodiment, an ion density of the first plasma incident on the substrate W may be controlled to perform a substrate process in which a reaction (an etching reaction) by ions of the first plasma is dominant. Therefore, at least some of the first plasma incident on the substrate W through the distribution plates 160 may have a high ratio of ions relative to radicals. At least a portion of the first plasma incident on the substrate W may have a ratio of radicals to ions ranging from about 1:100 to about 1:1000. For example, the first plasma may have a ratio of radicals to ions of about 1000:1 or more, at least some of the first plasma incident on the substrate W may have a ratio of ions to radicals of about 1000:1 or more, and the second plasma may have a ratio of radicals to ions of about 1000:1 or more.

The first plasma generating device 141 and the second plasma generating device 142 may include coils. The first plasma generating device 141 may include a first coil surrounding at least a portion of an upper surface or at least a portion of a side surface of the upper chamber 111, and the second plasma generating device 142 may include a second coil surrounding at least a portion of an upper surface or at least a portion of a side surface of the lower chamber 112. In an example embodiment, an inner diameter of the second plasma generating device 142 (or “the second coil”) may be longer than an outer diameter of the first plasma generating device 141 (or “the first coil”). For example, the second plasma having a relatively low electron temperature may be generated due to a difference in diameter between the first coil and the second coil. The outer diameter of the first coil may be about 300 mm or less, such as from about 50 mm to about 3M mm, from about 100 mm to about 300 mm, or from about 150 mm to about 3 mm. The inner diameter of the second coil may be greater than about 300 mm, such as greater than about 300 mm and less than or equal to about 1000 mm, greater than about 300 mm and less than or equal to about 800 mm, greater than about 300 mm and less than or equal to about 500 mm, or the like. Therefore, a width of the second plasma region P2 defined by an internal space of the lower chamber 112 may be greater than a width of the first plasma region P1 defined by an internal space of the upper chamber 111.

The first plasma generating device 141 may apply a magnetic field to the first process gas, based on a first RF power supplied from a first RF power source 140A. The second plasma generating device 142 may apply a magnetic field to the second process gas, based on a second RF power supplied from a second RF power source 140B. According to an example embodiment, the first plasma and the second plasma may be independently generated by alternately applying the first RF power and the second RF power to the first plasma generating device 141 and the second plasma generating device 142. A section to which the first RF power is applied and a section to which the second RF power is applied may not overlap each other. Depending on process conditions, the section (e.g., time period) to which the first RF power is applied and the section (e.g., time period) to which the second RF power is applied may partially overlap. For example, the first plasma generating device 141 and the second plasma generating device 142 may be operated alternately, but both the first plasma generating device 141 and the second plasma generating device 142 may be operated in some sections.

A first pump 170A and a second pump 170B may be connected to the lower chamber 112. The first pump 170A and the second pump 170B may be connected to an internal space of the chamber 110 through, for example, a cavity of the lower chamber 112 or the like. The first pump 170A and the second pump 170B may exhaust gas including remaining gas in the chamber 110 through the cavity of the lower chamber 112, and may control pressure. The first pump 170A and the second pump 170B may include vacuum pumps, and may include, for example, dry pumps, rotary pumps, diffusion pumps, turbo molecular pumps, ion pumps, or the like. For example, the first pump 170A may include a turbo molecular pump, and the second pump 170B may include a dry pump. In this case, the first pump 170A may have a higher exhaust speed than an exhaust speed of the second pump 170B, and may have a lower pressure range according to an operation.

The first pressure regulator 171 and the second pressure regulator 172 may be connected to the first pump 170A and the second pump 170B, respectively, to control pressure in the chamber 110 by the first pump 170A and the second pump 170B. The first pressure regulator 171 and the second pressure regulator 172 may include, for example, an automatic pressure controller (APC), respectively. Valves 175 may be disposed between the first pump 170A and the second pump 170B and between the second pump 170B and the second pressure regulator 172, to control flow of gas. According to embodiments, types, the number, arrangements, or the like of the first pump 170A, the second pump 170B, the first pressure regulator 171, the second pressure regulator 172, and valves 175, constituting an exhaust assembly, may be variously changed.

The controller 150 may process the substrate using the ions included in the first plasma and the radicals included in the second plasma. The controller 150 may be configured to alternately operate the first plasma generating device 141 and the second plasma generating device 142. The controller 150 may control the first RF power source 140A and the second RF power source 140B, to alternately apply the first RF power and the second RF power to the first plasma generating device 141 and the second plasma generating device 142. The controller 150 may include various memories and processors, to repeatedly operate the first plasma generating device 141 and the second plasma generating device 142 according to an etching amount of the substrate W, or to terminate the substrate processing. The memories and the processors may be implemented in hardware, firmware, software, or any combination thereof. For example, the processor may include a computing device such as a workstation computer, a desktop computer, a laptop computer, a tablet computer, or the like. The memories and the processors may be implemented by, for example, a general-purpose computer or application-specific hardware such as a digital signal processor (DSP), a field programmable gate array (FPGA), an application specific integrated circuit (ASIC), or the like. According to embodiments, the controller 150 may include at least one processor and memory storing computer instructions. The computer instructions, when executed by the at least one processor, may be configured to cause the controller to perform its functions.

The distribution plates 160 may be disposed between the first plasma region P1 and the second plasma region P2. The distribution plates 160 may be disposed below the first plasma region P1 in the upper chamber 111. A width of each of the distribution plates 160 may be equal to or greater than a width of the substrate W, but is not limited thereto. The distribution plates 160 may include a first plate 161 adjacent to the first plasma region P1, a second plate 162 disposed below the first plate 161, and a third plate 163 disposed below the second plate 162. The distribution plates 160 may be configured to accelerate the ions included in the first plasma, and may control a path thereof to make the same incident on the substrate W. For example, a first voltage (e.g., positive voltage) may be applied to the first plate 161, a second voltage (e.g., negative voltage), lower than the first voltage, may be applied to the second plate 162, and a reference voltage (a ground GND) (“a third voltage”) may be applied to the third plate 163.

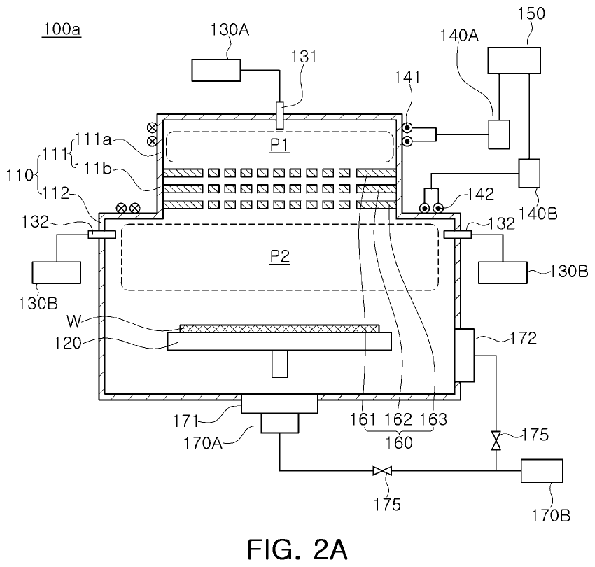

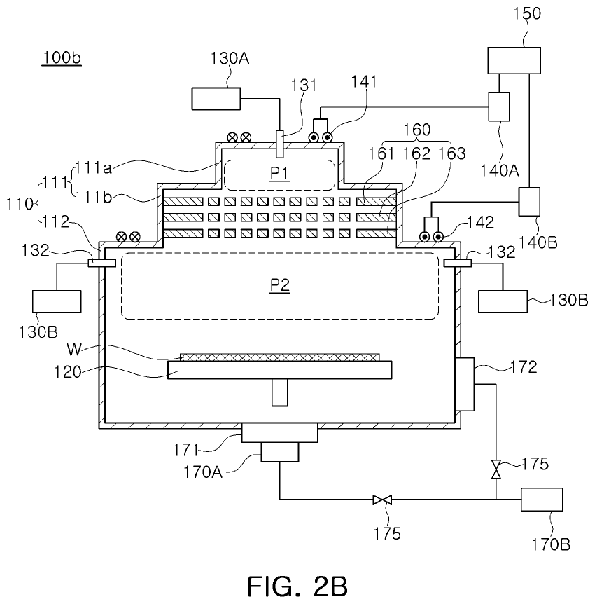

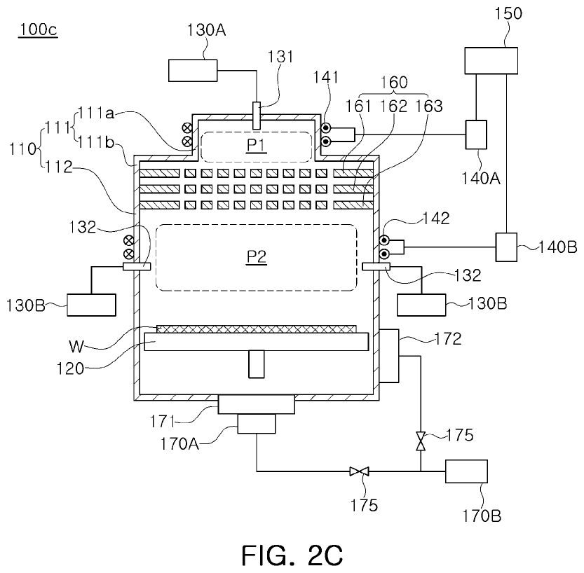

FIGS. 2A to 2C are cross-sectional views of a substrate processing apparatus 100a, a substrate processing apparatus 100b, and a substrate processing apparatus 100c, respectively, according to example embodiments.

Referring to FIG. 2A, the substrate processing apparatus 100a according to an example embodiment may have the same or similar features as those described with reference to FIG. 1, except that a width of a upper chamber 111 is constant. The upper chamber 111 may include an ion supplier 11a in which a first plasma region P1 is formed, and an ion distributor 111b configured to inject ions included in first plasma onto a substrate W. In the present embodiment, a width of the ion supplier 111a may be the same as a width of the ion distributor 111b. The ion supplier 111a may be formed such that an outer diameter of a first plasma generating device 141 surrounding a side surface thereof is narrower than an inner diameter of a second plasma generating device 142. Also in the present embodiment, a width of a first plasma region P1 may be narrower than a width of a second plasma region P2.

Referring to FIG. 2B, the substrate processing apparatus 100b of an example embodiment may have the same or similar features as those described with reference to FIGS. 1 and 2A, except that a first plasma generating device 141 is disposed on an upper surface of an upper chamber 111. The first plasma generating device 141 may include a coil surrounding at least a portion of the upper surface of the upper chamber 111. An outer diameter of the first plasma generating device 141 may be narrower than an inner diameter of a second plasma generating device 142. The outer diameter of the first plasma generating device 141 may be about 300 mm or less.

Referring to FIG. 2C, the substrate processing apparatus 100c of an example embodiment may have the same or similar features as those described with reference to FIGS. 1 to 2B, except that a second plasma generating device 142 is disposed on a side surface of a lower chamber 112. The second plasma generating device 142 may be disposed to surround both sides of a second plasma region P2. According to an example embodiment, a width of the lower chamber 112 may be the same as a width of an ion distributor 111b of an upper chamber 111, but is not limited thereto.

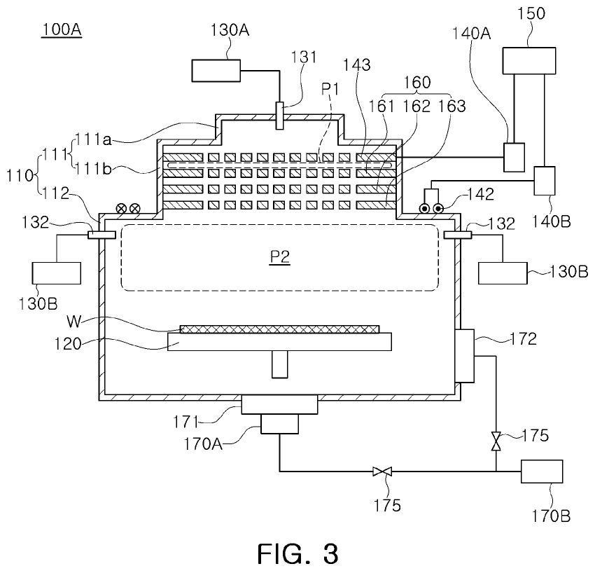

FIG. 3 is a schematic cross-sectional view of a substrate processing apparatus according to an example embodiment.

Referring to FIG. 3, a substrate processing apparatus 100A according to an example embodiment may be a device using a capacitively coupled plasma (CCP) method. The substrate processing apparatus 100A may include a first plasma generating device 143 in a form of an electrode. The first plasma generating device 143 may include at least one electrode plate disposed on distribution plates 160. The first plasma generating device 143 may receive RF power from a first RF power source 140A and form a high-frequency electric field in a first plasma region P1. The first plasma region P1 may be formed between the first plasma generating device 143 and a first plate 161. A controller 150 may control the first RF power source 140A and a second RF power source 140B to alternately apply first RF power and second RF power to the first plasma generating device 143 and a second plasma generating device 142. In this manner, first plasma and second plasma may be formed in the first plasma region P1 and a second plasma region P2, respectively, to independently control an ion density and an ion energy of the first plasma, and to independently control a radical density of the second plasma.

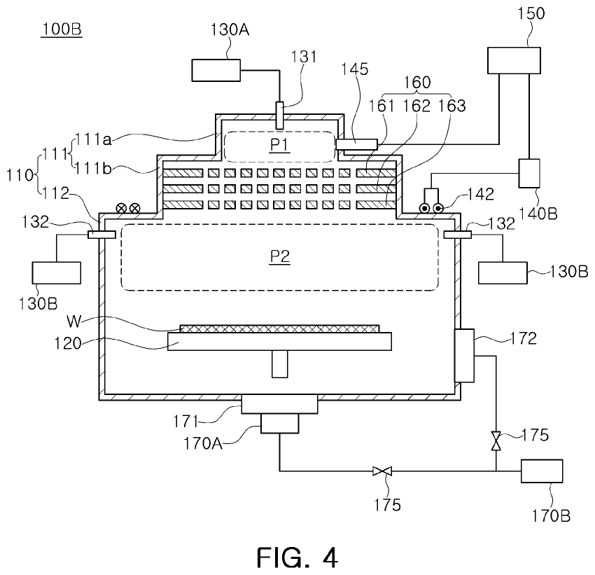

FIG. 4 is a schematic cross-sectional view of a substrate processing apparatus according to an example embodiment.

Referring to FIG. 4, a substrate processing apparatus 100B according to an example embodiment may be a device using a remote plasma source (RPS) method. A first plasma generating device 145 may introduce microwaves, externally generated, into a first plasma region P1. The microwaves introduced by the first plasma generating device 145 may be generated by, for example, a patch antenna, a dipole antenna, a monopole antenna, a microstrip antenna, a slot antenna, a Yagi antenna, or the like. According to example embodiments, since first plasma may be generated by external microwaves, a first gas supply device 131 and/or a first RF power source (see first RF power source 140A in FIG. 1) may be omitted. In this manner, the first plasma and second plasma may be formed in the first plasma region P1 and the second plasma region P2, respectively, to independently control an ion density and an ion energy of the first plasma, and to independently control a radical density of the second plasma.

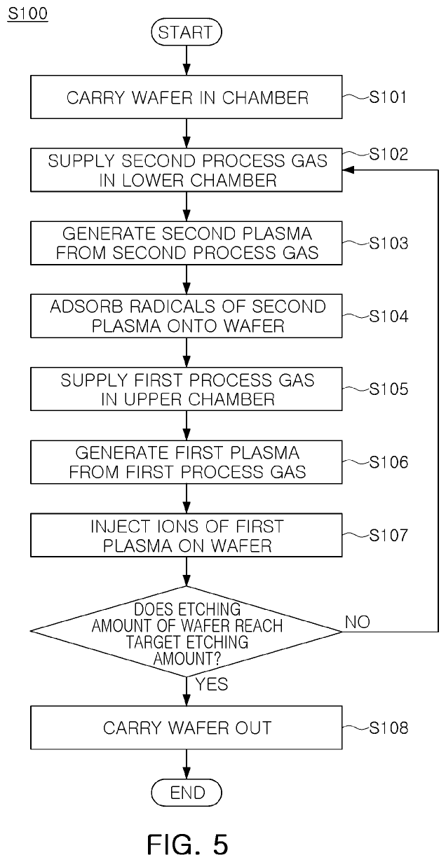

FIG. 5 is a flowchart illustrating a substrate processing method (S100) using a substrate processing apparatus according to example embodiments.

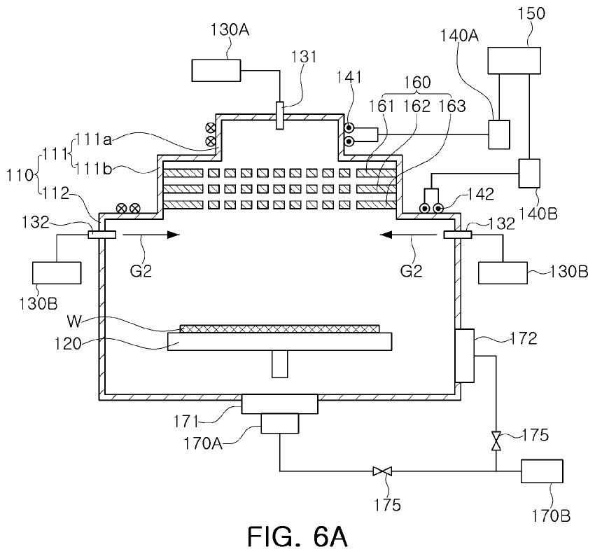

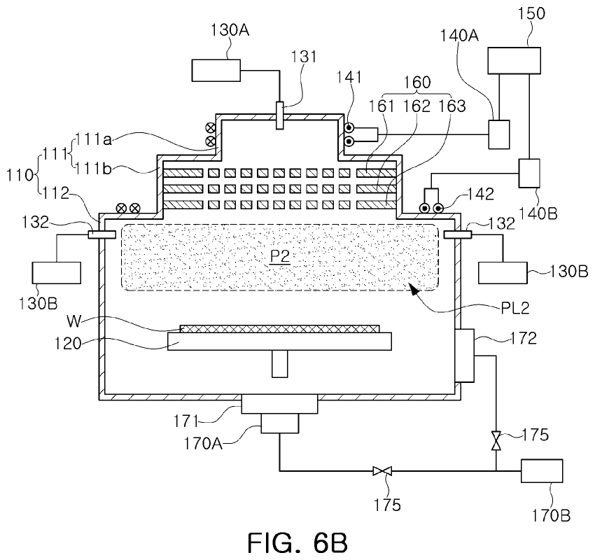

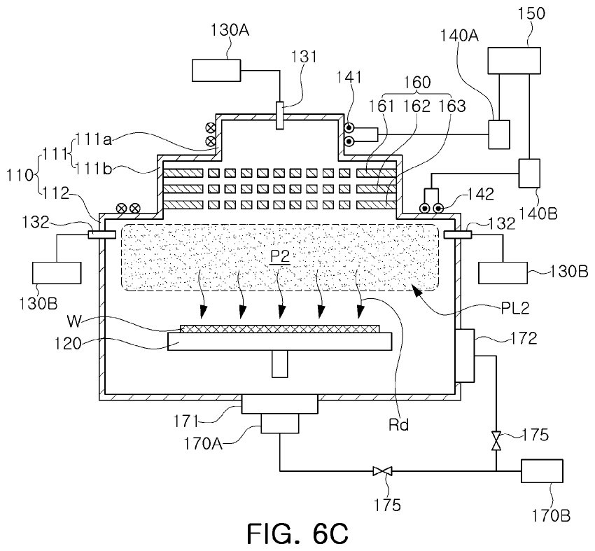

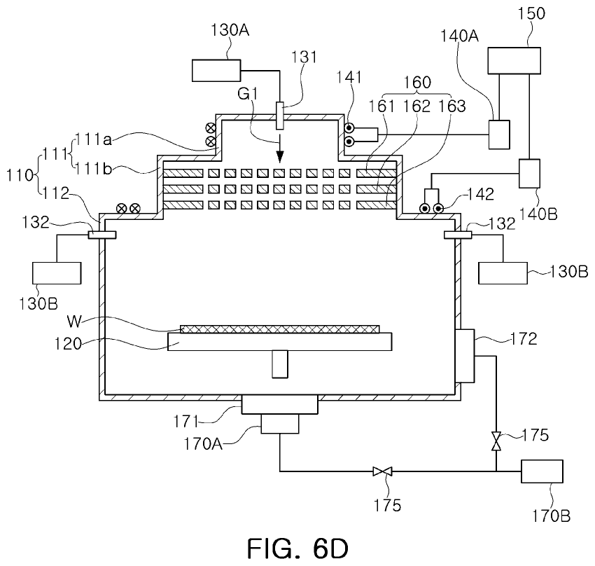

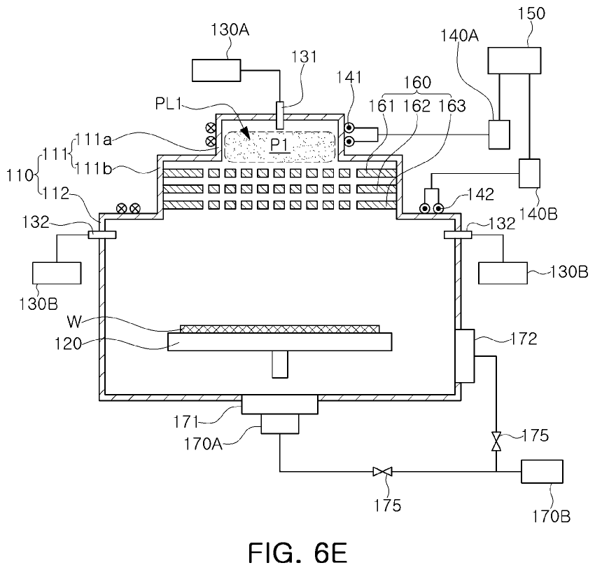

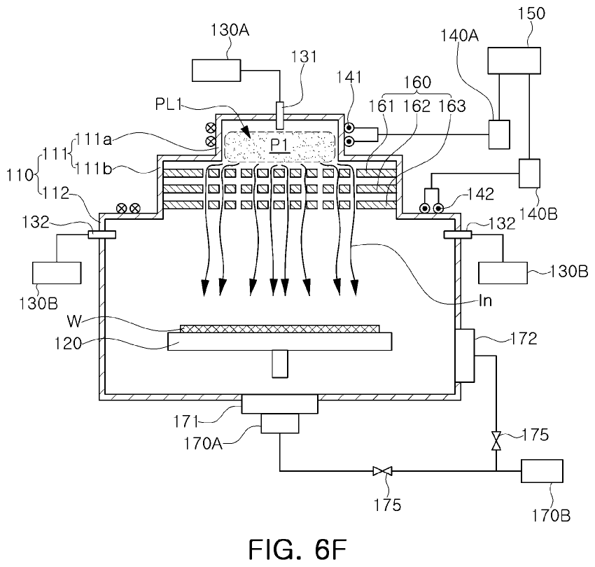

FIGS. 6A to 6F are views illustrating the substrate processing method (S100) of FIG. 5 according to a process sequence.

Referring to FIG. 5 and FIGS. 6A-6F, the substrate processing method (S100) of an example embodiment may include carrying in a substrate W (e.g., a wafer)(S101), supplying a second process gas G2 (step S102), generating second plasma PL2 (step S103), processing the substrate W using radicals Rd of the second plasma PL2 (step S104), supplying a first process gas G1 (step S105), generating first plasma PL1 (step S106), processing the substrate W using ions In of the first plasma PL1 (S107), and, when an etching amount of the substrate W does not reach a target etching amount, repeating step S102 to step S107 or when an etching amount of the substrate W reaches a target etching amount, carrying out the substrate W (step S108).

According to an example embodiment, the processing operations (step S105 to step S107) using the first plasma PL1 may be performed earlier than the processing operations (step S102 to step S104) using the second plasma PL2.

According to an example embodiment, the processing operations (step S102 to step S104) using the second plasma PL2 and the processing operations (step S105 to step S107) using the first plasma PL1 may be performed concurrently in at least portion of processing sections (e.g., time periods of processing). For example, while the operation (step S104) of processing the substrate W using the radicals Rd of the second plasma PL2 may be performed, the operation (step S105) of supplying the first process gas G1 may be performed.

In addition, between the processing operations (step S102 to step S104) using the second plasma PL2 and the processing operations (step S105 to step S107) using the first plasma P1, the first and second processing operations (step S105 to step S107), an operation of using a first pump 170A and a second pump 170B to exhaust residual radicals, residual ions, residual gas, or the like in a chamber 110 may be further performed.

Referring to FIGS. 5 and 6A to 6C, when a substrate W is inserted into the chamber 110 and place on a substrate support 120 (step S101), a second process gas G2 may be supplied into a lower chamber 112 through a second gas supply device 132 (step S102). The second gas supply device 132 may be connected to a second gas supply source 130B supplying the second process gas G2. The second process gas G2 may include, for example, at least one from among Cl₂, HCl, CHF₃, CH₂F₂, CH₃F, H₂, BCl₃, SiCl₄, Br₂, HBr, NF₃, CF₄, C₂F₆, C₄F₆, C₄F₈, SF₆, O₂, SO₂, and COS, but is not limited thereto.

Next, a second plasma generating device 142 may generate second plasma PL2 from the second process gas G2 based on second RF power supplied from a second RF power source 140B (step S103). The second plasma PL2 may include ions and radicals of the second process gas G2. The second plasma PL2 may be generated as plasma in which the radicals predominate over the ions. A ratio of radicals to ions in the second plasma PL2 may be about 1000:1 or more.

Next, radicals Rd of the second plasma PL2 may be adsorbed to a surface of the substrate W (step S104). Since the second plasma PL2 may be plasma in which the radicals predominate over the ions, the radicals Rd may be mainly adsorbed on the surface of the substrate W. Residual radicals and residual gases not adsorbed on the surface of the substrate W may be exhausted by first and second pumps 170A and 170B.

Referring to FIGS. 5 and 6D to 6F, after processing by the second plasma is completed, a first process gas G1 may be supplied into an upper chamber 111 through a first gas supply device 131 (step S105). The first gas supply device 131 may be connected to a first gas supply source 130A supplying the first process gas G1. The first process gas 01 may include, for example, at least one from among He, Ne, Ar, Kr, or Xe, but is not limited thereto.

Next, a first plasma generating device 141 may generate first plasma PL1 from the first process gas G1 based on first RF power supplied from a first RF power source 140A (step S106). The first plasma PL1 may include ions and radicals of the first process gas G1. The first plasma PL1 may be generated as plasma in which the radicals predominate over the ions. As described above, at least a portion of the first plasma PL1 incident on the substrate W may be predominately the ions. The at least a portion of the first plasma PL1 incident on the substrate W may have a ratio of ions to radicals of about 1000:1 or more.

Next, ions In of the first plasma PL1 may be incident on the surface of the substrate W (step S107). Distribution plates 160 may mainly accelerate the ions In of the first plasma PL1, and may control a path thereof to carry the same in on the substrate W. For example, a positive voltage may be applied to a first plate 161, a negative voltage may be applied to a second plate 162, and a reference voltage (“GND”) may be applied to a third plate 163. Therefore, a substrate processing operation in which a reaction (an etching reaction) by the ions In of the first plasma predominate may be performed. After performing the substrate processing operation using the ions in, remaining gases may be exhausted by the first pump 170A and the second pump 170B.

When the processing operations (step S102 to step S104) using the second plasma PL2 and the processing operations (step S105 to step S107) using the first plasma PL1 are completed, a controller 150 may select a subsequent process based on an etching amount of the substrate W. For example, when the etching amount of the substrate W does not reach a target etching amount, the operations illustrated in FIGS. 6A to 6F may be repeatedly performed. When the etching amount of the substrate W reaches the target etching amount, the substrate W may be carried out of, for example, the chamber 110 (step S108).

In this manner, the first plasma PL1 and the second plasma PL2 may be formed in separate regions in the chamber 110, an ion density and an ion energy of the first plasma PL1 used for processing the substrate W may be independently controlled, and a radical density of the second plasma PL2 used for processing the substrate W may be independently controlled. Therefore, a substrate processing method (S100) according to example embodiments may more effectively perform a substrate processing process, for example, a substrate etching process.

According to embodiments of the present disclosure, a substrate processing apparatus capable of independently controlling radicals may be provided.

Various advantages and effects of the embodiments of the present disclosure are not limited to the above, and other advantages and effects of the embodiments of the present disclosure should be understood based on above descriptions of non-limiting example embodiments of the present disclosure.

While example embodiments have been illustrated and described above, it will be apparent to those skilled in the art that modifications and variations can be made without departing from the scope of the present disclosure.

What is claimed is:

1. A substrate processing apparatus comprising:
a chamber comprising an upper chamber defining a first plasma region for generating first plasma, and the chamber further comprising a lower chamber defining a second plasma region for generating second plasma;
a substrate support below the first plasma region and the second plasma region in the lower chamber, and configured to support a substrate;
distribution plates between the first plasma region and the second plasma region in the upper chamber, and configured to inject ions included in the first plasma onto the substrate;
a first gas supply device configured to supply a first process gas to the first plasma region of the upper chamber;
a second gas supply device configured to supply a second process gas to the second plasma region of the lower chamber;
a first plasma generating device on at least one side of the upper chamber and configured to generate the first plasma from the first process gas;
a second plasma generating device on at least one side of the lower chamber and configured to generate the second plasma from the second process gas; and
a controller configured to alternately operate the first plasma generating device and the second plasma generating device.

2. The substrate processing apparatus of claim 1, wherein the distribution plates are configured to inject the ions such that at least a portion of the first plasma incident on the substrate via the distribution plates has a ratio of ions to radicals of 100:1 or more.

3. The substrate processing apparatus of claim 1, wherein the second plasma is a plasma having a ratio of radicals to ions of 100:1 or more.

4. The substrate processing apparatus of claim 1, wherein the first process gas comprises an inert gas, and
the second process gas comprises an etching gas.

5. The substrate processing apparatus of claim 4, wherein the inert gas comprises at least one from among He, Ne, Ar, Kr, and Xe.

6. The substrate processing apparatus of claim 4, wherein the etching gas comprises at least one from among Cl₂, HCl, CHF₃, CH₂F₂, CH₃F, H₂, BCl₃, SiCl₄, Br₂, HBr, NF₃, CF₄, C₂F₆, C₄F₆, C₄F₈, SF₆, O₂, SO₂, and COS.

7. The substrate processing apparatus of claim 1, further comprising:
a first radio frequency (RF) power source configured to apply a first RF power to the first plasma generating device; and
a second RF power source configured to apply a second RF power to the second plasma generating device.

8. The substrate processing apparatus of claim 7, wherein the controller is configured to control the first RF power source and the second RF power source such that the first RF power and the second RF power are alternately applied.

9. The substrate processing apparatus of claim 1, wherein the distribution plates comprise a first plate adjacent to the first plasma region, a second plate below the first plate, and a third plate below the second plate.

10. The substrate processing apparatus of claim 9, wherein a first voltage is applied to the first plate,
a second voltage, lower than the first voltage, is applied to the second plate, and
a reference voltage is applied to the third plate.

11. A substrate processing apparatus comprising:
a chamber comprising an upper chamber defining a first plasma region, and the chamber further comprising a lower chamber defining a second plasma region;
a substrate support in the lower chamber and configured to support a substrate;
a first gas supply device configured to supply a first process gas to the first plasma region of the upper chamber;
a second gas supply device configured to supply a second process gas to the second plasma region of the lower chamber;
a first plasma generating device on at least one side of the upper chamber and configured to generate first plasma from the first process gas; and
a second plasma generating device disposed on at least one side of the lower chamber and configured to generate second plasma from the second process gas,
wherein a width of the second plasma region is greater than a width of the first plasma region.

12. The substrate processing apparatus of claim 11, wherein the first plasma generating device comprises a first coil surrounding at least a portion of an upper surface of the upper chamber or at least a portion of a side surface of the upper chamber,
wherein the second plasma generating device comprises a second coil surrounding at least a portion of an upper surface of the lower chamber or at least a portion of a side surface of the lower chamber, and
wherein an inner diameter of the second coil is longer than an outer diameter of the first coil.

13. The substrate processing apparatus of claim 12, wherein the outer diameter of the first coil is 300 mm or less, and
the inner diameter of the second coil is greater than 300 mm.

14. The substrate processing apparatus of claim 11, wherein an electron temperature of the second plasma is lower than an electron temperature of the first plasma.

15. The substrate processing apparatus of claim 11, wherein the upper chamber comprises:
an ion supplier in which the first plasma generating device is configured to generate the first plasma; and
an ion distributor configured to inject ions included in the first plasma onto the substrate.

16. The substrate processing apparatus of claim 15, wherein a width of the ion distributor is greater than a width of the ion supplier.

17. A substrate processing apparatus comprising:
a first plasma generating device configured to generate first plasma in a first plasma region of the substrate processing apparatus;
a second plasma generating device configured to generate second plasma in a second plasma region of the substrate processing apparatus;
a substrate support below the second plasma region and configured to support a substrate; and
a controller configured to process the substrate using ions included in the first plasma and radicals included in the second plasma.

18. The substrate processing apparatus of claim 17, wherein the controller is configured to alternately apply radio frequency (RF) power to the first plasma generating device and the second plasma generating device.

19. The substrate processing apparatus of claim 17, wherein the first plasma has a ratio of radicals to ions of 1000:1 or more,
at least a portion of the first plasma incident on the substrate has a ratio of ions to radicals of 1000:1 or more, and
the second plasma has a ratio between radicals and ions of about 1000:1 or more.

20. The substrate processing apparatus of claim 17, further comprising distribution plates between the first plasma region and the second plasma region and configured to accelerate and inject the ions included in the first plasma onto the substrate.
